(19) United States
(12) Patent Application Publication
(10) Pub. No.: US 2026/0314508 A1
(43) Pub. Date: Oct. 8, 2026

(54) SEMICONDUCTOR PACKAGE

(71) Applicant: Samsung Electronics Co., Ltd., Suwon-si (KR)

(72) Inventors: Eunjung Lee, Suwon-si (KR); Heewoo An, Suwon-si (KR); Kihong Jeong, Suwon-si (KR)

(21) Appl. No.: 19/640,701

(22) Filed: Apr. 7, 2026

(30) Foreign Application Priority Data
Apr. 7, 2025 (KR) 10-2025-0044928

(51) Int. Cl. H10W 90/00; H10W 90/24

(52) U.S. Cl. CPC H10W 90/792; H10W 90/24; H10W 90/762

(57) ABSTRACT

A semiconductor package includes a package substrate, at least one first semiconductor chip offset-stacked in a first direction on the package substrate, first semiconductor chip pads on a top surface of each of the at least one first semiconductor chip, at least one second semiconductor chip that is offset-stacked in the first direction on a first semiconductor chip positioned at an uppermost end of the at least one first semiconductor chip, second semiconductor chip on a top surface of each of the at least one second semiconductor chip, and a plurality of substrate pads arranged in two rows on the package substrate, where a second semiconductor chip positioned at a lowermost end of the at least one second semiconductor chip is offset-stacked in the first and second directions with the first semiconductor chip positioned at the uppermost end.

### CROSS-REFERENCE TO RELATED APPLICATION

This application is based on and claims priority under 35 U.S.C. § 119 to Korean Patent Application No. 10-2025-0044928, filed on Apr. 7, 2025, in the Korean Intellectual Property Office, the disclosure of which is incorporated by reference herein in its entirety.

### BACKGROUND

Due to the rapid development of the electronics industry and user needs, electronic devices are becoming more compact and lightweight, and as a result, high integration and large capacity of semiconductor devices, which are core components of electronic devices, may be desired, but high integration of semiconductor devices is reaching a limit. Accordingly, a semiconductor package including a plurality of semiconductor chips has been developed to achieve large capacity.

### SUMMARY

As the demand for large capacity of semiconductor devices increases, semiconductor packages in which a plurality of semiconductor chips included in the semiconductor package are stacked may be developed. A plurality of semiconductor chips may be stacked in a semiconductor package, and a method of connecting the stacked semiconductor chips with a package substrate via wiring formed by wire bonding or patterning between the plurality of semiconductor chips and the package substrate may be contemplated.

Implementations according to the present disclosure provide a semiconductor package with improved signal characteristics.

Furthermore, implementations are not limited to the tasks described above, and other tasks may be clearly understood by one of ordinary skill in the art from the following description.

An aspect of the present disclosure provides a semiconductor package including a package substrate, at least one first semiconductor chip offset-stacked in a first direction on the package substrate, first semiconductor chip pads arranged to be spaced apart from each other in a second direction on a top surface of each of the at least one first semiconductor chip, at least one second semiconductor chip that is offset-stacked in the first direction on a first semiconductor chip positioned at an uppermost end of the at least one first semiconductor chip, second semiconductor chip pads arranged to be spaced apart from each other in the second direction on a top surface of each of the at least one second semiconductor chip, and a plurality of substrate pads arranged in two rows on the package substrate, where a second semiconductor chip positioned at a lowermost end of the at least one second semiconductor chip is offset-stacked in the first and second directions on the first semiconductor chip positioned at the uppermost end.

Another aspect of the present disclosure provides a semiconductor package including a package substrate, a first chip stack structure including a plurality of first semiconductor chips offset-stacked in a first direction on the package substrate, first semiconductor chip pads arranged in parallel to be spaced apart from each other in a second direction on a top surface of each of the plurality of first semiconductor chips, a second chip stack structure that is offset-stacked in the first direction and a second direction on a top surface of a first semiconductor chip positioned at an uppermost end of the plurality of first semiconductor chips, the second chip stack structure including a plurality of second semiconductor chips that are offset-stacked in the first direction) second semiconductor chip pads arranged to be spaced apart from each other in the second direction on a top surface of each of the plurality of second semiconductor chips, a plurality of substrate pads arranged in a first row and a second row on the package substrate, conductive patterns connecting the first semiconductor chip pad to the substrate pad and the second semiconductor chip pad to the substrate pad, and an insulating pattern positioned between the conductive patterns facing each other in a vertical direction, where the substrate pads are divided into ground/power substrate pads and signal substrate pads, the plurality of substrate pads positioned in each of the first row and the second row include the ground/power substrates pad and the signal substrate pads which are alternately positioned, the ground/power substrate pads face each other diagonally when viewed from above in the vertical direction, and the signal substrate pads face each other diagonally when viewed from above in the vertical direction.

Another aspect of the present disclosure provides a semiconductor package including a package substrate, a first chip stack structure including a plurality of first semiconductor chips offset-stacked in a first direction on the package substrate, first semiconductor chip pads arranged in parallel to be spaced apart from each other in a second direction on a top surface of each of the plurality of first semiconductor chips, a second chip stack structure that is offset-stacked in the first direction and a second direction on a top surface of a first semiconductor chip positioned at an uppermost end of the plurality of first semiconductor chips, the second chip stack structure including a plurality of second semiconductor chips that are offset-stacked in the first direction second semiconductor chip pads arranged to be spaced apart from each other in the second direction on a top surface of each of the plurality of second semiconductor chips, substrate pads arranged in a first row and a second row on the package substrate, conductive patterns connecting the first semiconductor chip pad to the substrate pad and the second semiconductor chip pad to the substrate pad, and an insulating pattern positioned between the conductive patterns facing each other in a vertical direction, where the substrate pads are divided into ground/power substrate pads and signal substrate pads, the plurality of substrate pads positioned in each of the first row and the second row include the ground/power substrate pads and the signal substrate pads which are alternately positioned, the ground/power substrate pads face each other diagonally when viewed from above in the vertical direction, the signal substrate pads face each other diagonally when viewed from above in the vertical direction, the conductive patterns include ground/power conductive patterns and signal conductive patterns, which are alternately positioned, substrate pads positioned in the first row among the substrate pads overlap the first semiconductor chip pads in the first direction, substrate pads positioned in the second row among the substrate pads overlap the second semiconductor chip pads in the first direction, and at least one of the substrate pads positioned in the first row does not overlap at least one of the substrate pads positioned in the second row in the first direction.

### BRIEF DESCRIPTION OF THE DRAWINGS

FIG. 1 is a perspective view schematically illustrating an example of a semiconductor package.

FIG. 2 is a plan view schematically illustrating the semiconductor package of FIG. 1.

FIG. 3 is a schematic diagram schematically illustrating first and second substrate pads of the semiconductor package of FIG. 1.

FIG. 4 is a cross-sectional view taken along the line A1-A1' of FIG. 2.

FIG. 5 is a cross-sectional view taken along the line A2-A2' of FIG. 2.

FIG. 6 is a plan view schematically illustrating an example of a semiconductor package.

FIG. 7 is a cross-sectional view taken along the line B1-B1' of FIG. 6.

FIG. 8 is a cross-sectional view taken along the line B2-B2' of FIG. 6.

FIG. 9 is a plan view schematically illustrating an example of a semiconductor package.

FIG. 10 is a side view schematically illustrating the semiconductor package of FIG. 9.

FIG. 11 is a plan view schematically illustrating an example of a semiconductor package.

FIGS. 12 to 17 are cross-sectional views illustrating a method of manufacturing an example of a semiconductor package.

### DETAILED DESCRIPTION

Hereinafter, implementations will be described in detail with reference to the accompanying drawings. The same reference numerals are used for the same components in the drawings, and redundant descriptions thereof will be omitted.

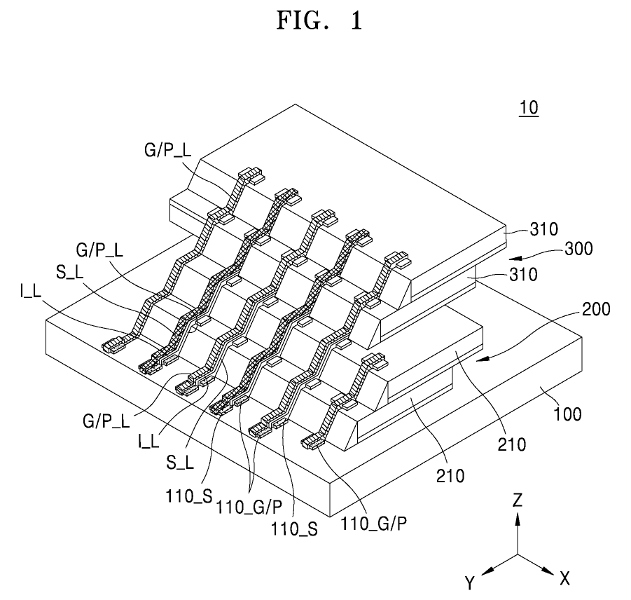

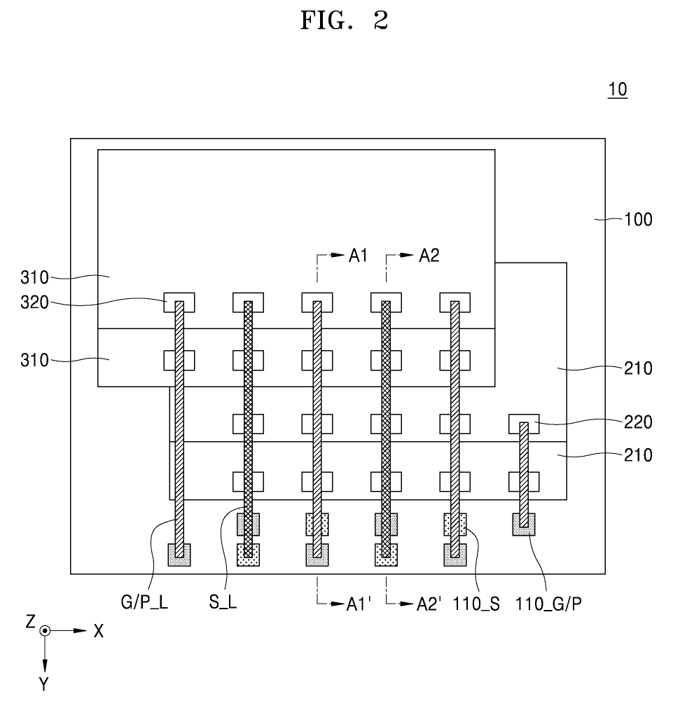

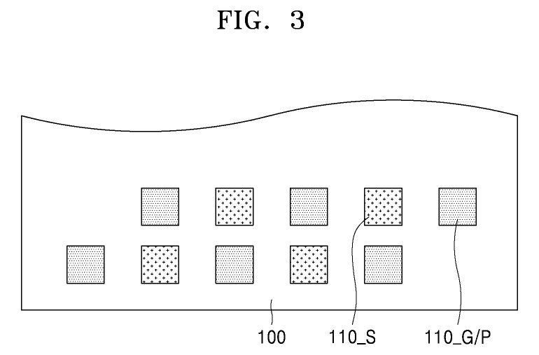

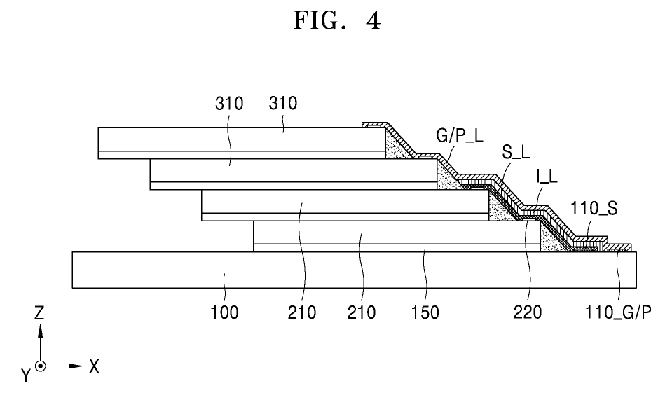

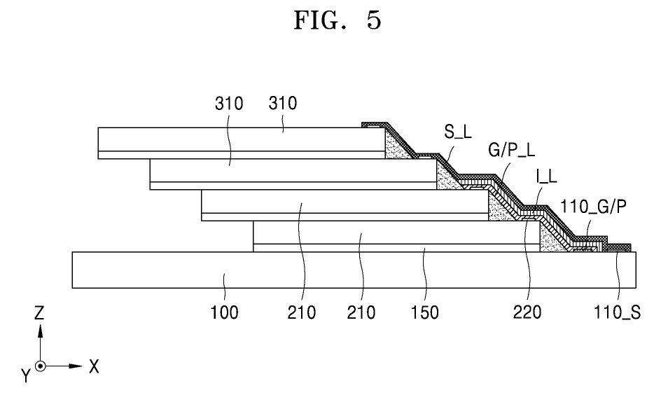

FIG. 1 is a perspective view schematically illustrating a semiconductor package according to some implementations. FIG. 2 is a plan view schematically illustrating the semiconductor package of FIG. 1. FIG. 3 is a schematic diagram schematically illustrating first and second substrate pads of the semiconductor package of FIG. 1. FIG. 4 is a cross-sectional view taken along the line A1-A1' of FIG. 2. FIG. 5 is a cross-sectional view taken along the line A2-A2' of FIG. 2.

Referring to FIGS. 1 to 5, a semiconductor package 10 may include a package substrate 100, a plurality of substrate pads 110_S and 110_G/P, a first chip stack structure 200, a second chip stack structure 300, and conductive patterns G/P_L and S_L.

The package substrate 100 may be arranged under the first chip stack structure 200, and may be electrically connected to each of the first chip stack structure 200 and the second chip stack structure 300. According to some implementations, the package substrate 100 may be formed based on, for example, a ceramic substrate, a printed circuit board (PCB), an organic substrate, an interposer substrate, or the like. In addition, in some implementations, the package substrate 100 may include a redistribution structure. In some implementations, the package substrate 100 may include a body portion and a wiring. Some portions of the wiring may be exposed to a bottom surface of the package substrate 100 to function as bump pads on which external connection terminals are mounted.

In the drawings, an X-axis direction and a Y-axis direction indicate directions parallel to a top surface or a bottom surface of the package substrate 100, and the X-axis direction and the Y-axis direction may be perpendicular to each other. The Z-axis direction may indicate a direction perpendicular to the top surface or the bottom surface of the package substrate 100. In other words, the Z-axis direction may be a direction perpendicular to the XY plane.

In addition, in the following drawings, a first horizontal direction, a second horizontal direction, and a vertical direction may be understood as follows. The first horizontal direction may be understood as an X-axis direction, the second horizontal direction may be understood as a Y-axis direction, and the vertical direction may be understood as a Z-axis direction.

The external connection terminals may be positioned on the lower surface of the package substrate 100. A first external connection terminal may be electrically connected to an external device, for example, a motherboard, a PCB, a package substrate, etc. The first external connection terminal may be electrically connected to wiring patterns formed in the package substrate 100 through substrate pads attached to the bottom surface of the package substrate 100.

The external connection terminals may include solder balls. However, according to some implementations, the external connection terminals may have a structure including pillars and solder. The external connection terminals may include at least one of copper (Cu), silver (Ag), gold (Au), and tin (Sb).

The substrate pads 110_S and 110_G/P may be arranged on the top surface of the package substrate 100. A plurality of substrate pads 110_S and 110_G/P may be provided, and in some implementations, a plurality of substrate pads 110_S and 110_G/P may be arranged side by side in two rows on the package substrate 100. For example, the plurality of substrate pads 110_S and 110_G/P may be arranged in a first row and a second row. The first row may include substrate pads 110_S and 110_G/P adjacent to the first chip stack structure 200 and spaced apart from each other in the first horizontal direction X, and the second row may include substrate pads 110_S and 110_G/P spaced apart from the first row in the second horizontal direction Y and spaced apart from each other in the first horizontal direction X. The second row may be spaced apart from the first chip stack structure 200 in the second horizontal direction Y with the first row therebetween.

According to some implementations, the substrate pads 110_S and 110_G/P positioned in the first row may be spaced apart from each other in the first horizontal direction X at the first interval. The substrate pads 110_S and 110_G/P positioned in the second row may also be spaced apart from each other in the first horizontal direction X at the first interval.

According to some implementations, the substrate pads 110_S and 110_G/P positioned in the first row and the substrate pads 110_S and 110_G/P positioned in the second row may be arranged to be misaligned by the first interval, respectively. The substrate pads 110_S and 110_G/P positioned in the second row may be offset in the first horizontal direction X by the first interval with respect to the substrate pads 110_S and 110_G/P positioned in the first row. Accordingly, at least one of the substrate pads 110_S and 110_G/P positioned in the first row may not overlap the substrate pads 110_S and 110_G/P positioned in the second row in the second horizontal direction Y. In addition, at least one of the substrate pads 110_S and 110_G/P positioned in the second row may not overlap the substrate pads 110_S and 110_G/P positioned in the first row in the second horizontal direction Y.

According to some implementations, among the substrate pads 110_S and 110_G/P positioned in the first row, the substrate pads 110_S and 110_G/P positioned at the outermost side in the first horizontal direction, e.g., the +X direction, may not overlap the substrate pads 110_S and 110_G/P positioned in the second row in the second horizontal direction Y. Among the substrate pads 110_S and 110_G/P positioned in the first row, each of the substrate pads 110_S and 110_G/P, except for the substrate pads 110_S and 110_G/P positioned at the outermost side according to the positive first horizontal direction +X, may overlap any one of the substrate pads 110_S and 110_G/P positioned in the second row in the second horizontal direction Y.

According to some implementations, among the substrate pads 110_S and 110_G/P positioned in the second row, the substrate pads 110_S and 110_G/P positioned at the outermost side in the negative first horizontal direction, e.g., the -X direction, may not overlap the substrate pads 110_S and 110_G/P positioned in the first row in the second horizontal direction Y. Among the substrate pads 110_S and 110_G/P positioned in the second row, each of the substrate pads 110_S and 110_G/P, except for the substrate pads 110_S and 110_G/P positioned at the outermost side according to the negative first horizontal direction -X, may overlap any one of the substrate pads 110_S and 110_G/P positioned in the first row in the second horizontal direction Y. Here, the positive first horizontal direction and the negative first horizontal direction may be understood as opposite directions. In addition, the first horizontal direction may mean a direction in which the substrate pads 110_S and 110_G/P included in each of the first and second rows are arranged spaced apart from each other, and the second horizontal direction may mean a direction in which the first and second rows are spaced apart from each other.

According to some implementations, the substrate pads 110_S and 110_G/P may be divided into a ground/power substrate pad 110_G/P and a signal substrate pad 110_S. However, the substrate pads 110_S and 110_G/P are not divided only into the ground/power substrate pad 110_G/P and the signal substrate pad 110_S, and may also include other types of substrate pads.

According to some implementations, the substrate pads 110_S and 110_G/P positioned in the first row may include ground/power substrate pads 110_G/P and signal substrate pads 110_S which are alternately arranged. For example, as shown in FIGS. 1 and 2, when a substrate pad positioned at the outermost side in the first row in the positive first horizontal direction +X is the ground/power substrate pad 110_G/P, a substrate pad adjacent to the ground/power substrate pad 110_G/P in the first row in the negative first horizontal direction -X may be the signal substrate pad 110_S.

According to some implementations, the substrate pads 110_S and 110_G/P positioned in the second row may include ground/power substrate pads 110_G/P and signal substrate pads 110_S which are alternately arranged.

For example, as shown in FIGS. 1 and 2, when a substrate pad positioned at the outermost side in the second row in the positive first horizontal direction +X is the ground/power substrate pad 110_G/P, a substrate pad adjacent to the ground/power substrate pad 110_G/P in the first row in the negative first horizontal direction -X may be the signal substrate pad 110_S.

According to some implementations, the substrate pads 110_S and 110_G/P positioned in the first row and the substrate pads 110_S and 110_G/P overlapping each other in the second horizontal direction Y may be different types of substrate pads 110_S and 110_G/P. For example, when any one of the substrate pads 110_S and 110_G/P positioned in the first row is the ground/power substrate pad 110_G/P, a substrate pad positioned in the second row overlapping the substrate pad 110_G/P in the second horizontal direction Y may be the signal substrate pad 110_S.

According to some implementations, one of the substrate pads 110_S and 110_G/P positioned in each of the first row and the second row may be a different type of a substrate pad from adjacent substrate pads 110_S and 110_G/P in at least one of the first horizontal direction X and the second horizontal direction Y. For example, when a substrate pad positioned in the second row among the substrate pads 110_S and 110_G/P positioned on the line A1-A1′ with reference to FIG. 2 is the ground/power substrate pad 110_G/P, substrate pads positioned at both sides of the ground/power substrate pad 110_G/P in the first horizontal direction X and a substrate pad positioned in the first row overlapping in the second horizontal direction Y may all be signal substrate pads 110_S.

According to some implementations, in the substrate pads 110_S and 110_G/P, as shown in FIG. 3, the signal substrate pads 110_S and the ground/power substrate pads 110_G/P may be alternately arranged in the first horizontal direction X and the second horizontal direction Y. The ground/power substrate pads 110_G/P may be arranged to surround the signal substrate pad 110_S, and the signal substrate pads 110_S may be arranged to surround the ground/power substrate pad 110_G/P.

The signal substrate pad 110_S may be positioned between the ground/power substrate pads 110_G/P, and the ground/power substrate pad 110_G/P may be positioned between the signal substrate pads 110_S. The ground/power substrate pads 110_G/P may face each other in a diagonal direction when viewed from above in the vertical direction Z, and the signal substrate pads 110_S may face each other in a diagonal direction when viewed from above in the vertical direction Z.

In some implementations, the ground/power substrate pads 110_G/P may not overlap each other in the first direction. In addition, the signal substrate pads 110_S may not overlap each other in the first direction.

The first chip stack structure 200 may be arranged on the package substrate 100. The first chip stack structure 200 may be provided on the package substrate 100 to be spaced apart by a predetermined distance from the substrate pads 110_S and 110_G/P. According to some implementations, the first chip stack structure 200 may be spaced apart from the substrate pads 110_S and 110_G/P positioned in the second row in the second horizontal direction Y with the substrate pads 110_S and 110_G/P positioned in the first row therebetween.

The first chip stack structure 200 may include a first semiconductor chip 210 and a first semiconductor chip pad 220. The first chip stack structure 200 may include at least one first semiconductor chip 210. According to some implementations, the first chip stack structure 200 may include a plurality of first semiconductor chips 210. For example, as shown in FIG. 1, the first chip stack structure 200 may include two first semiconductor chips 210. However, the number of the first semiconductor chips 210 is not limited thereto. The plurality of first semiconductor chips 210 may be offset-stacked in the first direction. Therefore, the first chip stack structure 200 may have a structure in which a plurality of first semiconductor chips 210 are offset-stacked in the first direction. In other words, the first chip stack structure 200 may be a structure in which a plurality of first semiconductor chips 210 are stacked in a cascade type, that is, a stepwise type, in the first direction. Here, the first direction may be the same as the direction in which the first row and the second row are spaced apart from each other. For example, the first direction may be the same as the second horizontal direction Y. However, the first direction is not limited thereto, and the first direction may be various directions such as the first horizontal direction X.

According to some implementations, each of the first semiconductor chips 210 may be arranged such that a surface adjacent to an inactive surface of the semiconductor substrate faces the package substrate 100. That is, a bottom surface of each of the first semiconductor chips 210 may be a surface close to an inactive surface of the semiconductor substrate, and a top surface of each of the first semiconductor chips 210 may be a surface close to an active surface of the semiconductor substrate.

An adhesive layer 150 may be positioned on a bottom surface of each of the first semiconductor chips 210. The adhesive layer 150 may be a film having its own adhesive properties. For example, the adhesive layer 150 may be a double-sided adhesive film. In some implementations, the adhesive layer 150 may be a tape-shaped material layer, a liquid-phase coating curing material layer, or a combination thereof. In addition, the adhesive layer 150 may include a thermal setting structure, a thermal plastic structure, a UV cure material, or a combination thereof. The adhesive layer 150 may be referred to as a die attach film (DAF) or a non-conductive film (NCF).

As the first semiconductor chips 210 of the first chip stack structure 200 are stacked in a stepwise type in the first direction, a portion of the top surface of each of the first semiconductor chips 210 may be exposed. That is, each of the first semiconductor chips 210 may have a portion of the top surface not covered by another first semiconductor chip 210 stacked directly on the top surface thereof. When the first semiconductor chips 210 are stacked in the first direction, portions of top surfaces of the first semiconductor chips 210 in a direction opposite to the first direction may be exposed upward.

A first semiconductor chip pad 220 may be arranged on a top surface of each of the first semiconductor chips 210. According to some implementations, the first semiconductor chip pad 220 may be arranged on a region in which a portion of the top surface of each of the first semiconductor chips 210 is exposed upward. According to some implementations, the first semiconductor chip pad 220 may be provided in plurality. Each of the first semiconductor chip pads 220 may be arranged on an upwardly exposed region of a top surface of each of the plurality of first semiconductor chips 210. According to some implementations, the plurality of first semiconductor chip pads 220 may be arranged on top surfaces of the first semiconductor chips 210, respectively. According to some implementations, the first semiconductor chip pads 220 may be arranged side by side in the first horizontal direction X on the top surface of the first semiconductor chip 210. According to some implementations, the first semiconductor chip pads 220 may be spaced apart from each other at the first interval.

According to some implementations, the first semiconductor chip pads 220 may overlap the substrate pads 110_S and 110_G/P positioned in the first row in the second horizontal direction Y. In some implementations, the first semiconductor chip pads 220 positioned on one first semiconductor chip 210 and the substrate pads 110_S and 110_G/P positioned in the first row may correspond one-to-one, and the corresponding first semiconductor chip pads 220 and the substrate pads 110_S and 110_G/P may overlap each other in the second horizontal direction Y.

At least one of the first semiconductor chip pads 220 may not overlap all of the substrate pads 110_S and 110_G/P positioned in the second row in the second horizontal direction Y.

According to some implementations, the first semiconductor chips 210 included in the first chip stack structure 200 may form a first channel. Furthermore, the second semiconductor chips 310 included in the second chip stack structure 300 may form a second channel. The first channel and the second channel may operate independently.

According to some implementations, the first semiconductor chip 210 may be a memory chip or a logic chip. The memory chip may be, for example, a volatile memory chip such as dynamic random access memory (DRAM) or static random access memory (SRAM), or may be a nonvolatile memory chip, such as phase-change RAM (PRAM), magnetoresistive RAM (MRAM), ferroelectric RAM (FeRAM), or resistive RAM (RRAM). In addition, the logic chip may be, for example, a logic chip such as a central processing unit (CPU), a graphics processing unit (GPU), a microprocessor such as or an application processor (AP), an analog device, or a digital signal processor.

In some implementations, the first semiconductor chip 210 may be a NAND flash memory chip. In this case, the first chip stack structure 200 may be understood as a structure in which a plurality of NAND flash memory chips are offset-stacked in the first direction.

The second chip stack structure 300 may be stacked on the first chip stack structure 200. The second chip stack structure 300 may be offset-stacked on the first chip stack structure 200 in each of the first direction and a second direction.

Specifically, the second chip stack structure 300 may be stacked on the top surface of the first semiconductor chip 210 positioned at the uppermost end of the first chip stack structure 200. The second chip stack structure 300 may include at least one second semiconductor chip 310. According to some implementations, the second chip stack structure 300 may include a plurality of second semiconductor chips 310. As shown in FIG. 1, the second chip stack structure 300 may include two second semiconductor chips 310. However, the number of the second semiconductor chips 310 is not limited thereto.

The second semiconductor chip 310 positioned at the lowermost end may be offset-stacked in each of the first direction and the second direction on the top surface of the first chip stack structure 200. Here, the first direction may be a direction in which the first semiconductor chips 210 are offset-stacked, and the second direction may be a direction perpendicular to the first direction. According to some implementations, the second direction may be a negative first horizontal direction -X.

The plurality of second semiconductor chips 310 may be offset-stacked in the first direction. In other words, a plurality of second semiconductor chips 310 may be stacked in a cascade type, that is, a stepwise type, in the first direction.

The second semiconductor chip 310 positioned at the lowermost end of the second chip stack structure 300 may be offset-stacked in the first direction and the second direction on the first semiconductor chip 210 positioned at the uppermost end of the first chip stack structure 200, and the second semiconductor chip 310 positioned on the lowermost end of the second chip stack structure 300 may be offset-stacked in the first direction on the lowermost second semiconductor chip 310

As the second semiconductor chips 310 of the second chip stack structure 300 are stacked in a stepwise type in the first direction, a portion of the top surface of each of the second semiconductor chips 310 may be exposed. That is, each of the second semiconductor chips 310 may have a portion of the top surface not covered by another second semiconductor chip 310 stacked directly on the top surface thereof. When the second semiconductor chips 310 are stacked in the first direction, portions of top surfaces of the second semiconductor chips 310 in a direction opposite to the first direction may be exposed upward.

An adhesive layer 150 may be positioned on a bottom surface of each of the second semiconductor chips 310. The adhesive layer 150 may be substantially the same as the adhesive layer 150 positioned on the bottom surface of each of the first semiconductor chips 210.

Second semiconductor chip pads 320 may be arranged on a top surface of each of the second semiconductor chips 310. According to some implementations, the second semiconductor chip pads 320 may be arranged on a region in which a portion of the top surface of each of the second semiconductor chips 310 is exposed upward. According to some implementations, the second semiconductor chip pad 320 may be provided in plurality. Each of the second semiconductor chip pads 320 may be arranged on an upwardly exposed region of a top surface of each of the plurality of second semiconductor chips 310. According to some implementations, the plurality of second semiconductor chip pads 320 may be arranged on top surfaces of the second semiconductor chips 310, respectively. According to some implementations, the second semiconductor chip pads 320 may be arranged side by side in the first horizontal direction X on the top surface of the second semiconductor chip 310. According to some implementations, the second semiconductor chip pads 320 may be spaced apart from each other at the first interval.

According to some implementations, the second semiconductor chip pads 320 may overlap the substrate pads 110_S and 110_G/P positioned in the second row in the second horizontal direction Y. In some implementations, the second semiconductor chip pads 320 positioned on one second semiconductor chip 310 and the substrate pads 110_S and 110_G/P positioned in the second row may correspond one-to-one, and the corresponding second semiconductor chip pads 320 and the substrate pads 110_S and 110_G/P may overlap each other in the second horizontal direction Y.

Accordingly, the first semiconductor chip pads 220 arranged in a row on the first semiconductor chip 210 may correspond to the substrate pads 110_S and 110_G/P positioned in the first row in the second horizontal direction Y, and the second semiconductor chip pads 320 arranged in a row on the second semiconductor chip 310 may correspond to the substrate pads 110_S and 110_G/P positioned in the second row in the second horizontal direction Y.

At least one of the second semiconductor chip pads 320 may not overlap all of the substrate pads 110_S and 110_G/P positioned in the first row in the second horizontal direction Y.

According to some implementations, the second semiconductor chips 310 included in the second chip stack structure 300 may form a second channel. The second channel may operate independently of the first channel.

According to some implementations, the second semiconductor chip 310 may be a memory chip or a logic chip. The memory chip may be, for example, a volatile memory chip such as dynamic random access memory (DRAM) or static random access memory (SRAM), or may be a nonvolatile memory chip, such as phase-change RAM (PRAM), magnetoresistive RAM (MRAM), ferroelectric RAM (FeRAM), or resistive RAM (RRAM). In addition, the logic chip may be, for example, a logic chip such as a central processing unit (CPU), a graphics processing unit (GPU), a microprocessor such as or an application processor (AP), an analog device, or a digital signal processor.

In some implementations, the second semiconductor chip 310 may be a NAND flash memory chip. In this case, the second chip stack structure 300 may be understood as a structure in which a plurality of NAND flash memory chips are offset-stacked in the first direction.

According to some implementations, the second semiconductor chip 310 may be the same type of chip as the first semiconductor chip 210, but is not limited thereto, and the second semiconductor chip 310 and the first semiconductor chip 210 may be different types of chips.

The conductive patterns G/P_L and S_L may be configured to electrically connect the first semiconductor chip pads 220 with the substrate pads 110_S and 110_G/P and the second semiconductor chip pad 320 with the substrate pads 110_S and 110_G/P. According to some implementations, the conductive patterns G/P_L and S_L connecting the first semiconductor chip pad 220 with the substrate pads 110_S and 110_G/P may be formed on insulating blocks 170. In addition, portions of the conductive patterns G/P_L and S_L connecting the second semiconductor chip pad 320 with the substrate pads 110_S and 110_G/P that do not overlap insulating patterns I_L in the vertical direction may be positioned on the insulating block 170.

The insulating blocks 170 may have a right triangle shape in a cross section on the X-Z plane. The conductive patterns G/P_L and S_L may have a shape having an inclination without being bent in a cross section on the X-Z plane by the insulating block 170. In addition, the lengths of the conductive patterns G/P_L and S_L may be reduced by the insulating blocks 170.

The conductive patterns may be divided into a ground/power conductive pattern G/P_L and a signal conductive pattern S_L. The ground/power conductive pattern G/P_L may electrically connect the ground/power substrate pad 110_G/P with the first semiconductor chip pad 220 and the ground/power substrate pad 110_G/P with the second semiconductor chip pad 320. The signal conductive pattern S_L may electrically connect the signal substrate pad 110_S with the first semiconductor chip pad 220, and the signal substrate pad 110_S with the second semiconductor chip pad 320.

According to some implementations, the conductive patterns G/P_L and S_L may extend in the first direction when viewed from above in the vertical direction Z. Furthermore, the conductive patterns G/P_L and S_L may have a staircase shape in a cross section on the X-Z plane.

The conductive patterns G/P_L and S_L connecting the first semiconductor chip pads 220 with the substrate pads 110_S and 110_G/P may cover at least some portions of top surfaces of the first semiconductor chips 210 and at least a portion of a top surface of the package substrate 100.

The conductive patterns G/P_L and S_L connecting the second semiconductor chip pads 320 with the substrate pads 110_S and 110_G/P may cover at least some portions of top surfaces of the second semiconductor chips 310, the insulating patterns I_L, and at least a portion of a top surface of the package substrate 100.

The insulating patterns I_L may be configured to insulate between the conductive patterns G/P_L and S_L connecting the first semiconductor chip pads 220 with the substrate pads 110_S and 110_G/P and the conductive patterns G/P_L and S_L connecting the second semiconductor chip pads 320 with the substrate pads 110_S and 110_G/P. The conductive patterns G/P_L and S_L spaced apart from each other in the vertical direction Z with the insulating pattern I_L therebetween may be different types of conductive patterns G/P_L and S_L. For example, one of the conductive patterns G/P_L and S_L spaced apart in the vertical direction Z with the insulating pattern I_L therebetween may be a ground/power conductive pattern G/P_L, and the other thereof may be a signal conductive pattern S_L.

A plurality of conductive patterns G/P_L and S_L and a plurality of insulating patterns I_L may be provided. For example, as illustrated in FIG. 1, when a pattern in which conductive patterns G/P_L and S_L, insulating patterns I_L, and conductive patterns G/P_L and S_L are accumulated in the vertical direction Z is defined as a bundle pattern, a plurality of bundle patterns are provided, and the plurality of bundle patterns may be provided to be spaced apart from each other in the second direction. The second direction may be perpendicular to the first direction, and according to some implementations, the second direction may be a first horizontal direction X. Structures of neighboring bundle patterns may be different from each other. For example, any one bundle pattern may have a structure in which the ground/power conductive pattern G/P_L, the insulating pattern I_L, and the signal conductive pattern S_L are sequentially stacked in the vertical direction Z, and another bundle pattern adjacent to the bundle pattern may have a structure in which the signal conductive pattern S_L, the insulating pattern I_L, and the ground/power conductive pattern G/P_L are sequentially stacked in the vertical direction Z.

The first semiconductor chip pads 220 may be electrically connected to the substrate pads 110_S and 110_G/P positioned in the first row through conductive patterns G/P_L and S_L. Specifically, among the first semiconductor chip pads 220, the first semiconductor chip pads 220 connected to the ground/power substrate pads 110_G/P may be electrically connected to the ground/power conductive patterns G/P_L. The ground/power conductive patterns G/P_L may be electrically connected to the first semiconductor chip pads 220 that overlap the ground/power substrate pads 110_G/P among the first semiconductor chip pads 220 in the second horizontal direction Y. In addition, among the first semiconductor chip pads 220, the first semiconductor chip pads 220 connected to the signal substrate pads 110_S may be electrically connected to the signal conductive patterns S_L. The signal conductive patterns S_L may be electrically connected to the first semiconductor chip pads 220 that overlap the signal substrate pads 110_S among the first semiconductor chip pads 220 in the second horizontal direction Y.

Since the substrate pads 110_S and 110_G/P positioned in the first row are arranged so that the ground/power substrate pad 110_G/P and the signal substrate pad 110_S are alternately arranged at first intervals in the second direction, the conductive patterns G/P_L and S_L connecting the first semiconductor chip pads 220 with the substrate pads 110_S and 110_G/P positioned in the first row may also be alternately arranged while the ground/power conductive pattern G/P_L and the signal conductive pattern S_L are spaced apart from each other at the first interval in the second direction.

The second semiconductor chip pads 320 may be electrically connected to the substrate pads 110_S and 110_G/P positioned in the second row through the conductive patterns G/P_L and S_L. Specifically, among the second semiconductor chip pads 320, the second semiconductor chip pads 320 connected to the ground/power substrate pads 110_G/P may be electrically connected to the ground/power conductive patterns G/P_L. The ground/power conductive patterns G/P_L may be electrically connected to the second semiconductor chip pads 320 that overlap the ground/power substrate pads 110_G/P among the second semiconductor chip pads 320 in the second horizontal direction Y. In addition, among the second semiconductor chip pads 320, the second semiconductor chip pads 320 connected to the signal substrate pads 110_S may be electrically connected to the signal conductive patterns S_L. The signal conductive patterns S_L may be electrically connected to the second semiconductor chip pads 320 that overlap the signal substrate pads 110_S among the second semiconductor chip pads 320 in the second horizontal direction Y.

Since the substrate pads 110_S and 110_G/P positioned in the second row are arranged so that the ground/power substrate pad 110_G/P and the signal substrate pad 110_S are alternately arranged at the first interval in the second direction, the conductive patterns G/P_L and S_L connecting the second semiconductor chip pads 320 with the substrate pads 110_S and 110_G/P positioned in the second row may also be alternately arranged while the ground/power conductive pattern G/P_L and the signal conductive pattern S_L are spaced apart from each other at the first interval in the second direction.

Accordingly, the ground/power conductive patterns G/P_L may be positioned at both sides of the signal conductive pattern S_L in the first horizontal direction X and the side thereof in the vertical direction Z, and the signal conductive patterns S_L may be positioned at both sides of the ground/power conductive pattern G/P_L in the first horizontal direction X and the side thereof in the vertical direction Z.

In the semiconductor package 10 according to the inventive concept, the ground/power substrate pads 110_G/P may surround the signal substrate pad 110_S, and the ground/power conductive pattern G/P_L may surround the signal conductive pattern S_L. Accordingly, signal interference between the signal substrate pads 110_S and signal interference between the signal conductive patterns S_L may be minimized, and the return path of the signal may be formed more firmly at a closer distance, thereby reducing loop inductance. As a result, noise or distortion that may occur during signal transmission of the signal substrate pads 110_S and the signal conductive patterns S_L may be reduced, and thus signal integrity may be improved even in high-speed signals.

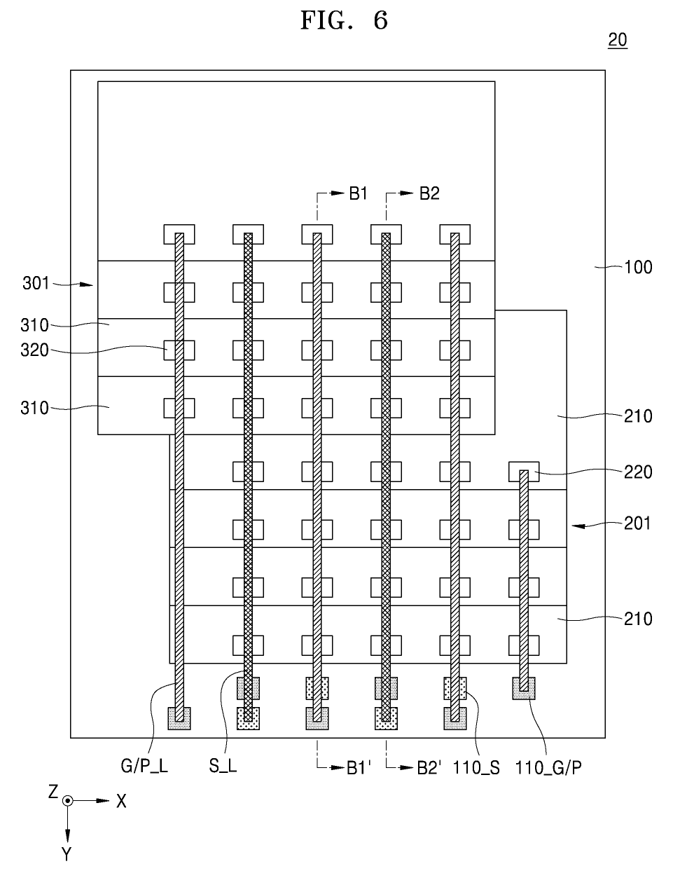

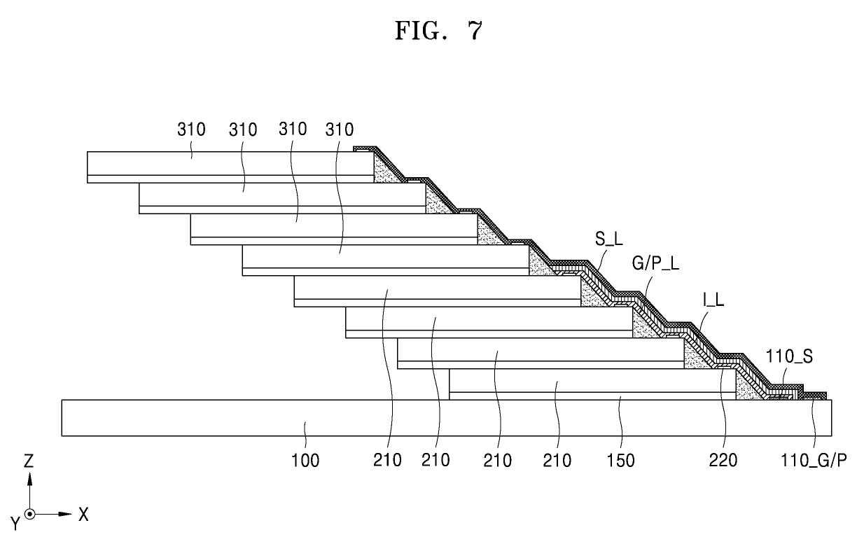

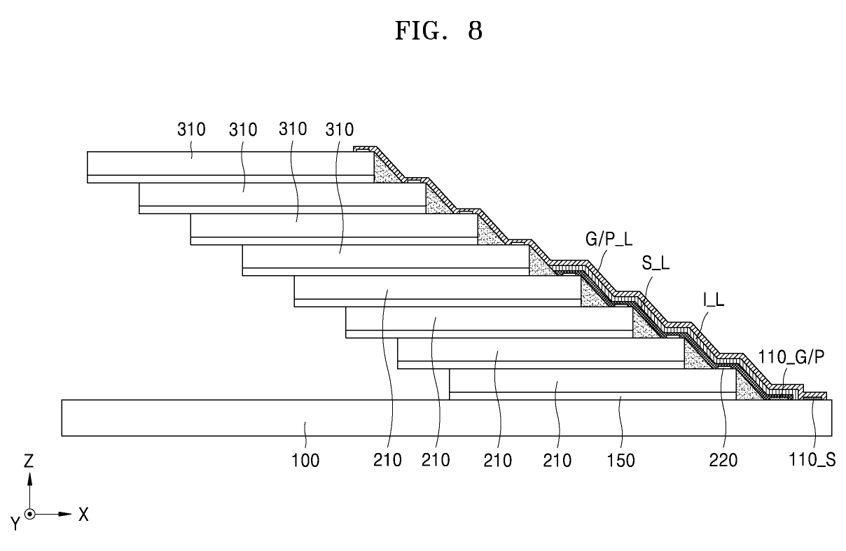

FIG. 6 is a plan view schematically illustrating a semiconductor package according to some implementations. FIG. 7 is a cross-sectional view taken along the line B1-B1' of FIG. 6. FIG. 8 is a cross-sectional view taken along the line B2-B2' of FIG. 6. Hereinafter, redundant descriptions with those described with reference to FIGS. 1 - 5 are omitted, and differences are mainly described.

Referring to FIGS. 6 - 8, a semiconductor package 20 may include the package substrate 100, a first chip stack structure 201, a second chip stack structure 301, and conductive patterns G/P_L and S_L.

The package substrate 100 may be arranged under the first chip stack structure 200, and may be electrically connected to each of the first chip stack structure 201 and the second chip stack structure 301.

The substrate pads 110_S and 110_G/P may be arranged on the top surface of the package substrate 100. A plurality of substrate pads 110_S and 110_G/P may be provided, and in some implementations, a plurality of substrate pads 110_S and 110_G/P may be arranged side by side in two rows on the package substrate 100.

For example, the plurality of substrate pads 110_S and 110_G/P may be arranged in a first row and a second row. The first row may include substrate pads 110_S and 110_G/P adjacent to the first chip stack structure 201 and spaced apart from each other in the first horizontal direction X, and the second row may include substrate pads 110_S and 110_G/P spaced apart from the first row in the second horizontal direction Y and spaced apart from each other in the first horizontal direction X. The second row may be spaced apart from the first chip stack structure 201 in the second horizontal direction Y with the first row therebetween.

According to some implementations, the substrate pads 110_S and 110_G/P positioned in the first row may be spaced apart from each other in the first horizontal direction X at the first interval. The substrate pads 110_S and 110_G/P positioned in the second row may also be spaced apart from each other in the first horizontal direction X at the first interval.

According to some implementations, the substrate pads 110_S and 110_G/P positioned in the first row and the substrate pads 110_S and 110_G/P positioned in the second row may be arranged to be misaligned by the first interval, respectively. The substrate pads 110_S and 110_G/P positioned in the second row may be offset in the first horizontal direction X by the first interval with respect to the substrate pads 110_S and 110_G/P positioned in the first row.

According to some implementations, among the substrate pads 110_S and 110_G/P positioned in the first row, the substrate pads 110_S and 110_G/P positioned at the outermost side in the first horizontal direction, e.g., the +X direction, may not overlap the substrate pads 110_S and 110_G/P positioned in the second row in the second horizontal direction Y. Among the substrate pads 110_S and 110_G/P positioned in the first row, each of the substrate pads 110_S and 110_G/P, except for the substrate pads 110_S and 110_G/P positioned at the outermost side according to the positive first horizontal direction +X, may overlap any one of the substrate pads 110_S and 110_G/P positioned in the second row in the second horizontal direction Y.

According to some implementations, the substrate pads 110_S and 110_G/P may be divided into the ground/power substrate pad 110_G/P and the signal substrate pad 110_S. According to some implementations, the substrate pads 110_S and 110_G/P positioned in the first row may include ground/power substrate pads 110_G/P and signal substrate pads 110_S which are alternately arranged.

According to some implementations, the substrate pads 110_S and 110_G/P positioned in the first row and the substrate pads 110_S and 110_G/P overlapping each other in the second horizontal direction Y may be different types of substrate pads 110_S and 110_G/P. For example, when any one of the substrate pads 110_S and 110_G/P positioned in the first row is the ground/power substrate pad 110_G/P, a substrate pad positioned in the second row overlapping the substrate pad 110_G/P in the second horizontal direction Y may be the signal substrate pad 110_S. According to some implementations, one of the substrate pads 110_S and 110_G/P positioned in each of the first row and the second row may be a different type of a substrate pad from adjacent substrate pads 110_S and 110_G/P in at least one of the first horizontal direction X and the second horizontal direction Y.

The first chip stack structure 201 may be arranged on the package substrate 100. The first chip stack structure 201 may be provided on the package substrate 100 to be spaced apart by a predetermined distance from the substrate pads 110_S and 110_G/P. According to some implementations, the first chip stack structure 201 may be spaced apart from the substrate pads 110_S and 110_G/P positioned in the second row in the second horizontal direction Y with the substrate pads 110_S and 110_G/P positioned in the first row therebetween.

The first chip stack structure 201 may include the first semiconductor chip 210 and the first semiconductor chip pad 220. The first chip stack structure 201 may include four first semiconductor chips 210. The four first semiconductor chips 210 may be offset-stacked in a first direction, and first semiconductor chip pads 220 may be positioned on a top surface of each of the four first semiconductor chips 210. An adhesive layer 150 may be positioned on a bottom surface of each of the first semiconductor chips 210.

A second semiconductor chip 310 positioned at the lowermost end of the second chip stack structure 301 may be offset-stacked in the first direction and the second direction on the first semiconductor chip 210 positioned at the uppermost end of the first chip stack structure 201, and another second semiconductor chip 310 positioned on the second semiconductor chip 310 positioned at the lowermost end thereof may be offset-stacked in the first direction on the second semiconductor chip 310 positioned at the lowermost end thereof.

As the second semiconductor chips 310 of the second chip stack structure 301 are stacked in a stepwise type in the first direction, a portion of the top surface of each of the second semiconductor chips 310 may be exposed. That is, each of the second semiconductor chips 310 may have a portion of the top surface not covered by another second semiconductor chip 310 stacked directly on the top surface thereof. When the second semiconductor chips 310 are stacked in the first direction, portions of top surfaces of the second semiconductor chips 310 in a direction opposite to the first direction may be exposed upward.

The second chip stack structure 301 may include four second semiconductor chips 310. An adhesive layer 150 may be positioned on a bottom surface of each of the second semiconductor chips 310. The adhesive layer 150 may be substantially the same as the adhesive layer 150 positioned on the bottom surface of each of the first semiconductor chips 210.

Second semiconductor chip pads 320 may be arranged on a top surface of each of the second semiconductor chips 310. According to some implementations, the second semiconductor chip pads 320 may be arranged on a region in which a portion of the top surface of each of the second semiconductor chips 310 is exposed upward.

The conductive patterns G/P_L and S_L may be configured to electrically connect the first semiconductor chip pads 220 with the substrate pads 110_S and 110_G/P and the second semiconductor chip pads 320 with the substrate pads 110_S and 110_G/P. The conductive patterns may be divided into a ground/power conductive pattern G/P_L and a signal conductive pattern S_L. The ground/power conductive pattern G/P_L may electrically connect the ground/power substrate pad 110_G/P with the first semiconductor chip pad 220 and the ground/power substrate pad 110_G/P with the second semiconductor chip pad 320. The signal conductive pattern S_L may electrically connect the signal substrate pad 110_S with the first semiconductor chip pad 220, and the signal substrate pad 110_S with the second semiconductor chip pad 320.

According to some implementations, the conductive patterns G/P_L and S_L may extend in the first direction when viewed from above in the vertical direction Z. Furthermore, the conductive patterns G/P_L and S_L may have a staircase shape in a cross section on the X-Z plane.

The conductive patterns G/P_L and S_L connecting the first semiconductor chip pads 220 with the substrate pads 110_S and 110_G/P may cover at least some portions of top surfaces of the first semiconductor chips 210 and at least a portion of a top surface of the package substrate 100.

The conductive patterns G/P_L and S_L connecting the second semiconductor chip pads 320 with the substrate pads 110_S and 110_G/P may cover at least some portions of top surfaces of the second semiconductor chips 310, the insulating patterns I_L, and at least a portion of a top surface of the package substrate 100.

The insulating patterns I_L may be configured to insulate between the conductive patterns G/P_L and S_L connecting the first semiconductor chip pads 220 with the substrate pads 110_S and 110_G/P and the conductive patterns G/P_L and S_L connecting the second semiconductor chip pads 320 with the substrate pads 110_S and 110_G/P. The conductive patterns G/P_L and S_L spaced apart from each other in the vertical direction Z with the insulating pattern I_L therebetween may be different types of conductive patterns G/P_L and S_L. For example, one of the conductive patterns G/P_L and S_L spaced apart in the vertical direction Z with the insulating pattern I_L therebetween may be a ground/power conductive pattern G/P_L, and the other thereof may be a signal conductive pattern S_L.

A plurality of conductive patterns G/P_L and S_L and a plurality of insulating patterns I_L may be provided. For example, as illustrated in FIGS. 6 - 8, when a pattern in which conductive patterns G/P_L and S_L, insulating patterns I_L, and conductive patterns G/P_L and S_L are accumulated in the vertical direction Z is defined as a bundle pattern, a plurality of bundle patterns are provided, and the plurality of bundle patterns may be provided to be spaced apart from each other in the second direction. The second direction may be perpendicular to the first direction, and according to some implementations, the second direction may be a first horizontal direction X. Structures of neighboring bundle patterns may be different from each other. For example, any one bundle pattern may have a structure in which the ground/power conductive pattern G/P_L, the insulating pattern I_L, and the signal conductive pattern S_L are sequentially stacked in the vertical direction Z, and another bundle pattern adjacent to the bundle pattern may have a structure in which the signal conductive pattern S_L, the insulating pattern I_L, and the ground/power conductive pattern G/P_L are sequentially stacked in the vertical direction Z.

The ground/power conductive patterns G/P_L may be positioned at both sides of the signal conductive pattern S_L in the first horizontal direction X and the side thereof in the vertical direction Z, and the signal conductive patterns S_L may be positioned at both sides of the ground/power conductive pattern G/P_L in the first horizontal direction X and the side thereof in the vertical direction Z.

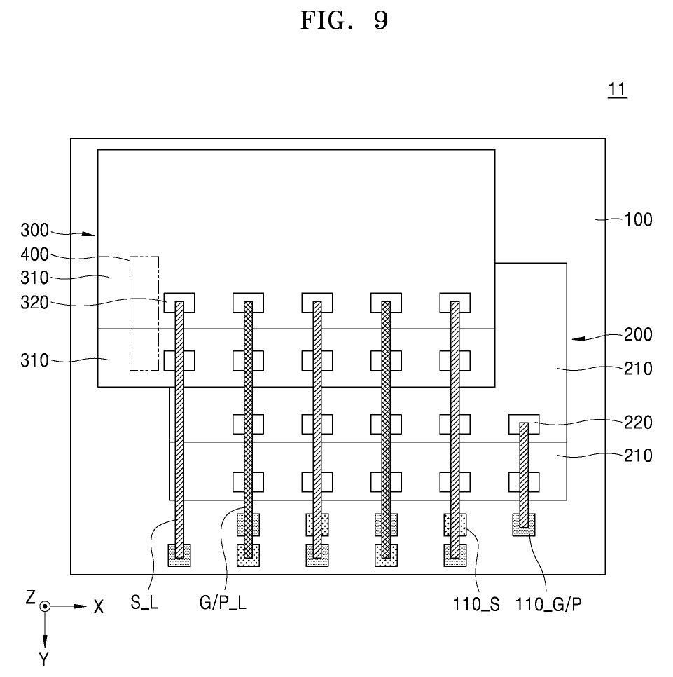

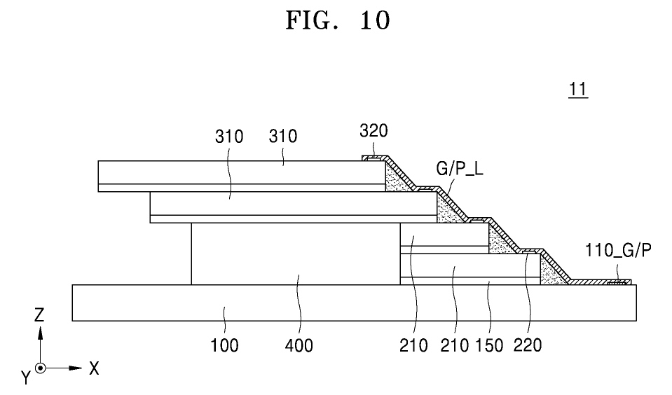

FIG. 9 is a plan view schematically illustrating a semiconductor package according to some implementations. FIG. 10 is a side view schematically illustrating the semiconductor package of FIG. 9. Hereinafter, descriptions overlapping with those described with reference to FIGS. 1 - 8 are omitted, and differences are mainly described.

Referring to FIGS. 9 and 10, a semiconductor package 11 may include the package substrate 100, the first chip stack structure 200, the second chip stack structure 300, and the conductive patterns G/P_L and S_L.

The package substrate 100 may be arranged under the first chip stack structure 200, and may be electrically connected to each of the first chip stack structure 200 and the second chip stack structure 300.

The substrate pads 110_S and 110_G/P may be arranged on the top surface of the package substrate 100. A plurality of substrate pads 110_S and 110_G/P may be provided, and in some implementations, a plurality of substrate pads 110_S and 110_G/P may be arranged side by side in two rows on the package substrate 100.

The first chip stack structure 200 may be arranged on the package substrate 100. The first chip stack structure 200 may be provided on the package substrate 100 to be spaced apart by a predetermined distance from the substrate pads 110_S and 110_G/P. According to some implementations, the first chip stack structure 200 may be spaced apart from the substrate pads 110_S and 110_G/P positioned in the second row in the second horizontal direction Y with the substrate pads 110_S and 110_G/P positioned in the first row therebetween.

The first chip stack structure 200 may include the first semiconductor chip 210 and the first semiconductor chip pad 220. According to some implementations, a plurality of first semiconductor chips 210 may be provided. The plurality of first semiconductor chips 210 may be offset-stacked in the first direction. A second semiconductor chip 310 positioned at the lowermost end of the second chip stack structure 300 may be offset-stacked in the first direction and the second direction on the first semiconductor chip 210 positioned at the uppermost end of the first chip stack structure 200, and another second semiconductor chip 310 positioned on the second semiconductor chip 310 positioned at the lowermost end thereof may be offset-stacked in the first direction on the second semiconductor chip 310 positioned at the lowermost end thereof.

As the second semiconductor chips 310 of the second chip stack structure 300 are stacked in a stepwise type in the first direction, a portion of the top surface of each of the second semiconductor chips 310 may be exposed. That is, each of the second semiconductor chips 310 may have a portion of the top surface not covered by another second semiconductor chip 310 stacked directly on the top surface thereof. When the second semiconductor chips 310 are stacked in the first direction, portions of top surfaces of the second semiconductor chips 310 in a direction opposite to the first direction may be exposed upward.

The second chip stack structure 300 may include a plurality of second semiconductor chips 310. An adhesive layer 150 may be positioned on a bottom surface of each of the second semiconductor chips 310. The adhesive layer 150 may be substantially the same as the adhesive layer 150 positioned on the bottom surface of each of the first semiconductor chips 210.

Second semiconductor chip pads 220 may be arranged on a top surface of each of the second semiconductor chips 310. According to some implementations, the second semiconductor chip pads 320 may be arranged on a region in which a portion of the top surface of each of the second semiconductor chips 310 is exposed upward.

According to some implementations, a support 400 may be positioned between the lowermost second semiconductor chip 310 and the package substrate 100. The support 400 may be positioned to support the lowermost second semiconductor chip 310 on the top surface of the package substrate 100. The support 400 may be configured to support a surface exposed from the first semiconductor chip 210 on the bottom surface of the lowermost second semiconductor chip 310. The lowermost second semiconductor chip 310 may be offset-stacked on the uppermost first semiconductor chip 210 in each of the first direction and the second direction. In this case, the support 400 may be positioned on the second direction side of the first semiconductor chip 210. When viewed from above in the vertical direction Z, the support 400 may be completely covered by the second chip stack structure 300. In some implementations, the support 400 may include a silicon dummy. As the support 400 supports the bottom surface of the lowermost second semiconductor chip 310, structural stability of the offset stacked second semiconductor chips 310 may be improved. In addition, since the support 400 is hidden from the second chip stack structure 300, the size of the semiconductor package 11 may be maintained.

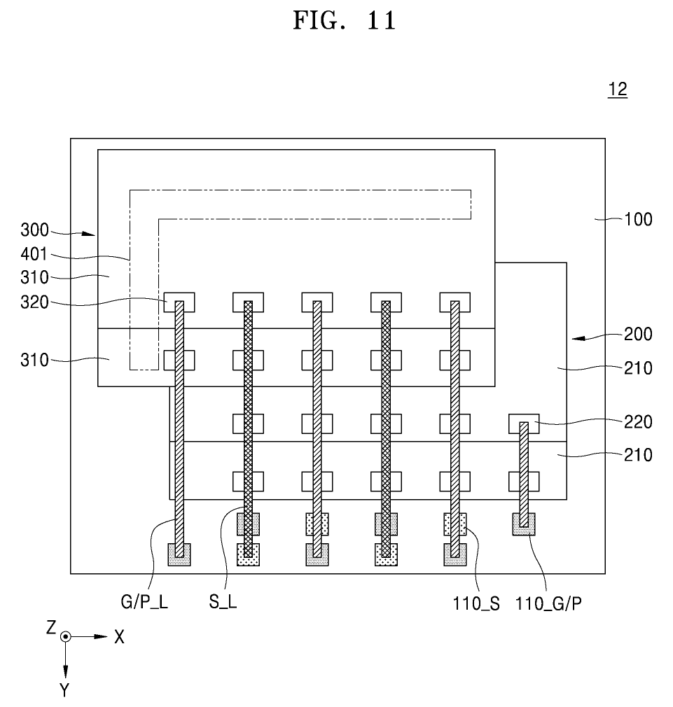

FIG. 11 is a plan view schematically illustrating a semiconductor package according to some implementations. Hereinafter, descriptions overlapping with those described with reference to FIGS. 1 - 10 are omitted, and differences are mainly described.

Referring to FIG. 11, a semiconductor package 12 may include the package substrate 100, the first chip stack structure 200, the second chip stack structure 300, and the conductive patterns G/P_L and S_L.

The package substrate 100 may be arranged under the first chip stack structure 200, and may be electrically connected to each of the first chip stack structure 201 and the second chip stack structure 301.

The substrate pads 110_S and 110_G/P may be arranged on the top surface of the package substrate 100. A plurality of substrate pads 110_S and 110_G/P may be provided, and in some implementations, a plurality of substrate pads 110_S and 110_G/P may be arranged side by side in two rows on the package substrate 100.

The first chip stack structure 200 may be arranged on the package substrate 100. The first chip stack structure 200 may be provided on the package substrate 100 to be spaced apart by a predetermined distance from the substrate pads 110_S and 110_G/P. According to some implementations, the first chip stack structure 200 may be spaced apart from the substrate pads 110_S and 110_G/P positioned in the second row in the second horizontal direction Y with the substrate pads 110_S and 110_G/P positioned in the first row therebetween.

The first chip stack structure 200 may include the first semiconductor chip 210 and the first semiconductor chip pad 220. According to some implementations, a plurality of first semiconductor chips 210 may be provided. The plurality of first semiconductor chips 210 may be offset-stacked in the first direction. A second semiconductor chip 310 positioned at the lowermost end of the second chip stack structure 300 may be offset-stacked in the first direction and the second direction on the first semiconductor chip 210 positioned at the uppermost end of the first chip stack structure 200, and another second semiconductor chip 310 positioned on the second semiconductor chip 310 positioned at the lowermost end thereof may be offset-stacked in the first direction on the second semiconductor chip 310 positioned at the lowermost end thereof.

As the second semiconductor chips 310 of the second chip stack structure 300 are stacked in a stepwise type in the first direction, a portion of the top surface of each of the second semiconductor chips 310 may be exposed. That is, each of the second semiconductor chips 310 may have a portion of the top surface not covered by another second semiconductor chip 310 stacked directly on the top surface thereof. When the second semiconductor chips 310 are stacked in the first direction, portions of top surfaces of the second semiconductor chips 310 in a direction opposite to the first direction may be exposed upward.

The second chip stack structure 300 may include a plurality of second semiconductor chips 310. An adhesive layer 150 may be positioned on a bottom surface of each of the second semiconductor chips 310. The adhesive layer 150 may be substantially the same as the adhesive layer 150 positioned on the bottom surface of each of the first semiconductor chips 210.

Second semiconductor chip pads 320 may be arranged on a top surface of each of the second semiconductor chips 310. According to some implementations, the second semiconductor chip pads 320 may be arranged on a region in which a portion of the top surface of each of the second semiconductor chips 310 is exposed upward.

According to some implementations, a support 401 may be positioned between the lowermost second semiconductor chip 310 and the package substrate 100. The support 401 may be positioned to support the lowermost second semiconductor chip 310 on the top surface of the package substrate 100. The support 401 may be configured to support a surface exposed from the first semiconductor chip 210 on the bottom surface of the lowermost second semiconductor chip 310.

According to some implementations, the support 401 may have a bent shape when viewed from above in the vertical direction Z. In some implementations, the support 401 may have a vertically bent shape when viewed from above in the vertical direction Z. In this case, the support 401 may be positioned to face the first semiconductor chip 210 in the first direction and the second direction. When viewed from above in the vertical direction Z, the support 401 may be completely covered by the second chip stack structure 300. In some implementations, the support 401 may include a silicon dummy. As the support 401 supports the bottom surface of the lowermost second semiconductor chip 310, structural stability of the offset stacked second semiconductor chips 310 may be improved. In addition, since the support 401 is hidden from the second chip stack structure 300, the size of the semiconductor package 11 may be maintained.

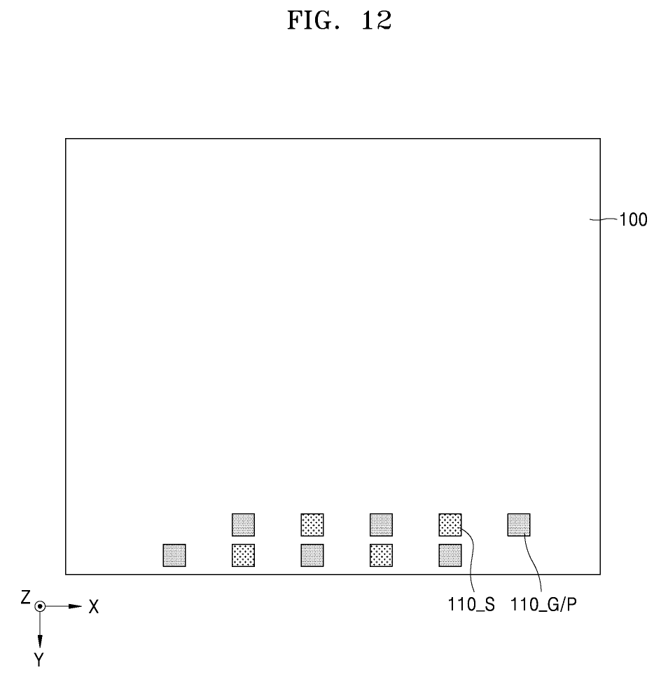

FIGS. 12- 17 are cross-sectional views illustrating a method of manufacturing a semiconductor package according to some implementations. Hereinafter, descriptions overlapping with those described with reference to FIGS. 1 -11 are omitted, and differences are mainly described.

Referring to FIG. 12, the package substrate 100 is provided in which substrate pads 110_S and 110_G/P are arranged on a top surface thereof. The substrate pads 110_S and 110_G/P may be arranged in two rows on the top surface of the package substrate 100. A first row and a second row may be spaced apart from each other in the second horizontal direction Y.

The substrate pads 110_S and 110_G/P positioned in the first row may be positioned such that the ground/power substrate pads 110_G/P and the signal substrate pads 110_S may be alternately spaced apart from each other at the first interval in the first horizontal direction X. The substrate pads 110_S and 110_G/P positioned in the second row may also be positioned such that the ground/power substrate pads 110_G/P and the signal substrate pads 110_S may be alternately spaced apart from each other at the first interval in the first horizontal direction X.

According to some implementations, the substrate pads 110_S and 110_G/P positioned in the first row and the substrate pads 110_S and 110_G/P positioned in the second row may be arranged to be misaligned by the first interval, respectively. The substrate pads 110_S and 110_G/P positioned in the second row may be offset in the first horizontal direction X by the first interval with respect to the substrate pads 110_S and 110_G/P positioned in the first row.

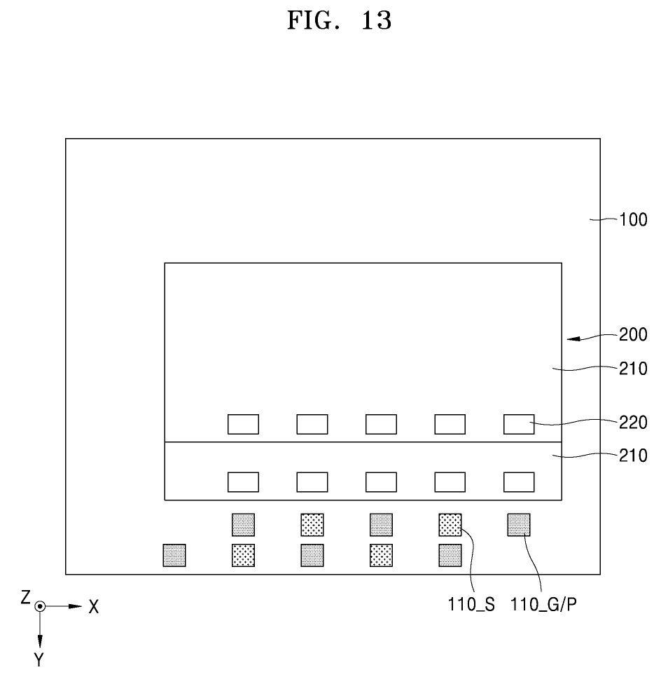

Referring to FIG. 13, the first chip stack structure 200 is mounted on the package substrate 100. The first chip stack structure 201 may include a plurality of first semiconductor chips 210. The plurality of first semiconductor chips 210 may be offset-stacked in the first direction. Side surfaces of the first semiconductor chips 210 may be coplanar.

A plurality of first semiconductor chip pads 220 may be positioned on a top surface of each of the first semiconductor chips 210. The plurality of first semiconductor chip pads 220 may be arranged on a region in which a portion of the top surface of each of the first semiconductor chips 210 is exposed upward. According to some implementations, the first semiconductor chip pads 220 may overlap the substrate pads 110_S and 110_G/P positioned in the first row in the second horizontal direction Y.

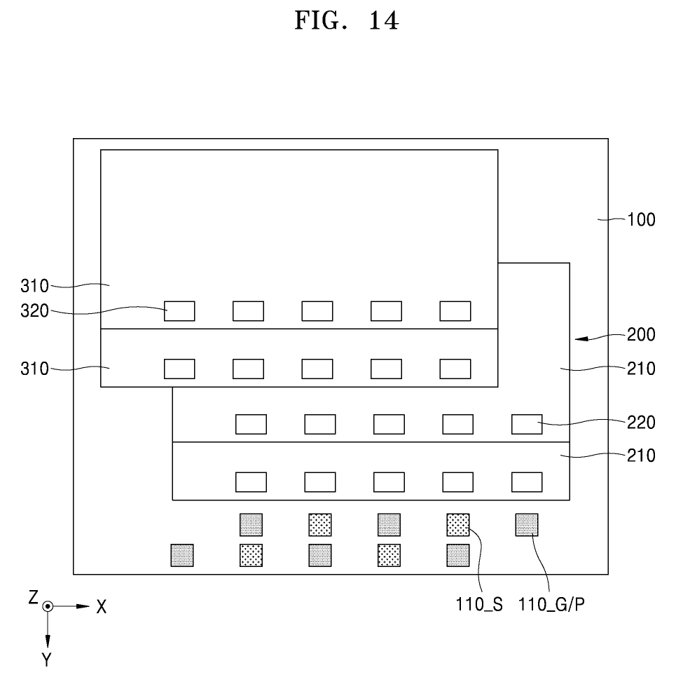

Referring to FIG. 14, the second chip stack structure 300 is mounted on the first chip stack structure 200. The second chip stack structure 300 may be offset-stacked on the first chip stack structure 200 in each of the first direction and the second direction. The second chip stack structure 300 may be stacked on the top surface of the first semiconductor chip 210 positioned at the uppermost end of the first chip stack structure 200.

The second chip stack structure 300 may include a plurality of second semiconductor chips 310. The second semiconductor chip 310 positioned at the lowermost end may be offset-stacked in each of the first direction and the second direction on the top surface of the first chip stack structure 200.

A plurality of second semiconductor chip pads 320 may be positioned on a top surface of each of the second semiconductor chips 310. The plurality of second semiconductor chip pads 320 may be arranged on a region in which a portion of the top surface of each of the second semiconductor chips 310 is exposed upward. According to some implementations, the second semiconductor chip pads 320 may overlap the substrate pads 110_S and 110_G/P positioned in the second row in the second horizontal direction Y.

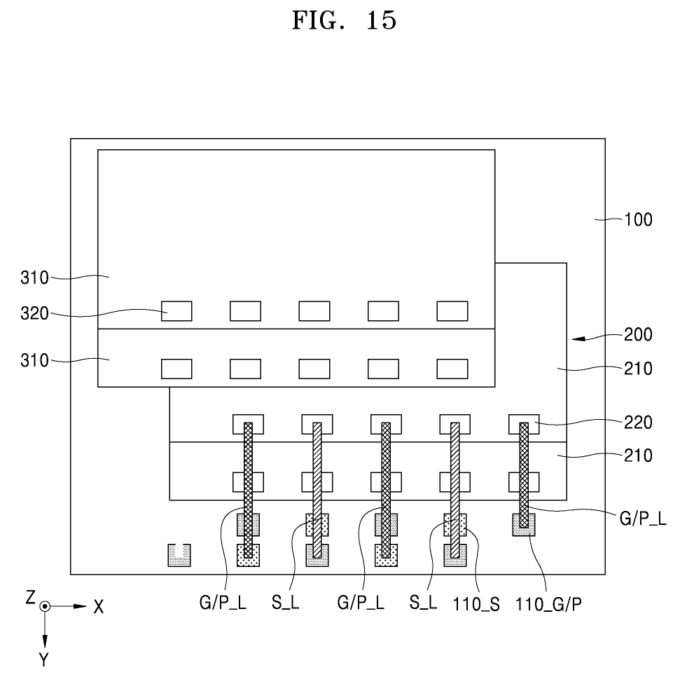

Referring to FIG. 15, the first semiconductor chip pads 220 on the first semiconductor chips 210 are electrically connected to the substrate pads 110_S and 110_G/P positioned in the first row through conductive patterns G/P_L and S_L.

The conductive patterns may be divided into a ground/power conductive pattern G/P_L and a signal conductive pattern S_L. The ground/power conductive patterns G/P_L may electrically connect the ground/power substrate pads 110_G/P with the first semiconductor chip pads 220. The signal conductive patterns S_L may electrically connect the signal substrate pads 110_S with the first semiconductor chip pads 220. The conductive patterns G/P_L and S_L may extend in the first direction when viewed from above in the vertical direction Z. Furthermore, the conductive patterns G/P_L and S_L may have a staircase shape in a cross section on the X-Z plane.

The conductive patterns G/P_L and S_L connecting the first semiconductor chip pads 220 with the substrate pads 110_S and 110_G/P may cover at least some portions of top surfaces of the first semiconductor chips 210 and at least a portion of a top surface of the package substrate 100.

The conductive patterns G/P_L and S_L may cover at least a portion of the top surface of each of the first semiconductor chip pads 220. In some implementations, the conductive patterns G/P_L and S_L may entirely cover the top surfaces of the first semiconductor chip pads 220. In some implementations, the conductive patterns G/P_L and S_L may entirely cover the top surfaces and the side surfaces of the first semiconductor chip pads 220. In some implementations, the conductive patterns G/P_L and S_L may cover only some portions of the top surfaces of the first semiconductor chip pads 220. In the present specification, the conductive patterns G/P_L and S_L connecting the first semiconductor chip pads 220 with the substrate pads 110_S and 110_G/P may be referred to as first conductive patterns.

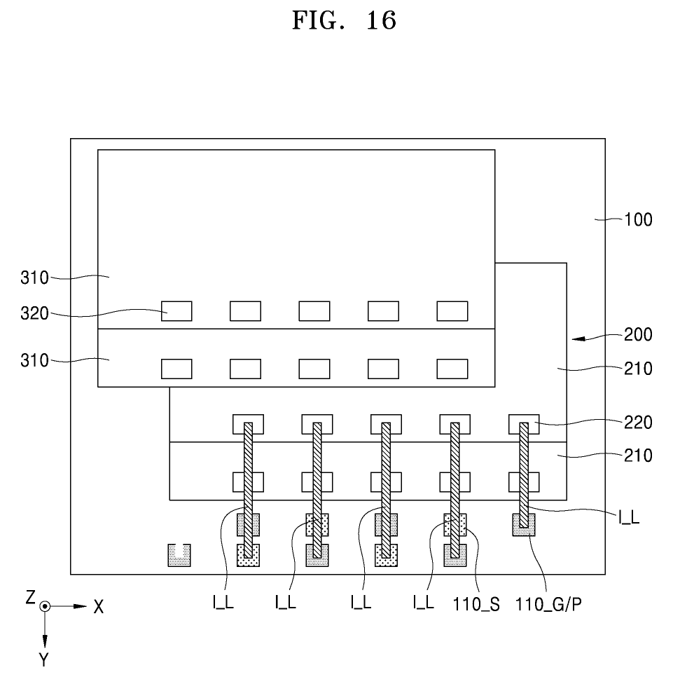

Referring to FIG. 16, insulating patterns I_L are respectively formed on the conductive patterns G/P_L and S_L electrically connecting the first semiconductor chip pads 220 with the substrate pads 110_S and 110_G/P positioned in the first row. The insulating patterns I_L may be formed to cover the conductive patterns G/P_L and S_L, which overlap the second semiconductor chips 310 among the conductive patterns G/P_L and S_L in the second horizontal direction Y. The insulating patterns I_L may not be formed on the conductive patterns G/P_L and S_L, which do not overlap the second semiconductor chips 310 among the conductive patterns G/P_L and S_L electrically connecting the first semiconductor chip pads 220 with the substrate pads 110_S and 110_G/P positioned in the first row, in the second horizontal direction Y.

The insulating patterns I_L may be formed to surround the conductive patterns G/P_L and S_L. In some implementations, the insulating patterns I_L may cover only the top surfaces of the conductive patterns G/P_L and S_L. In some implementations, the insulating patterns I_L may entirely cover the exposed surfaces of the conductive patterns G/P_L and S_L.

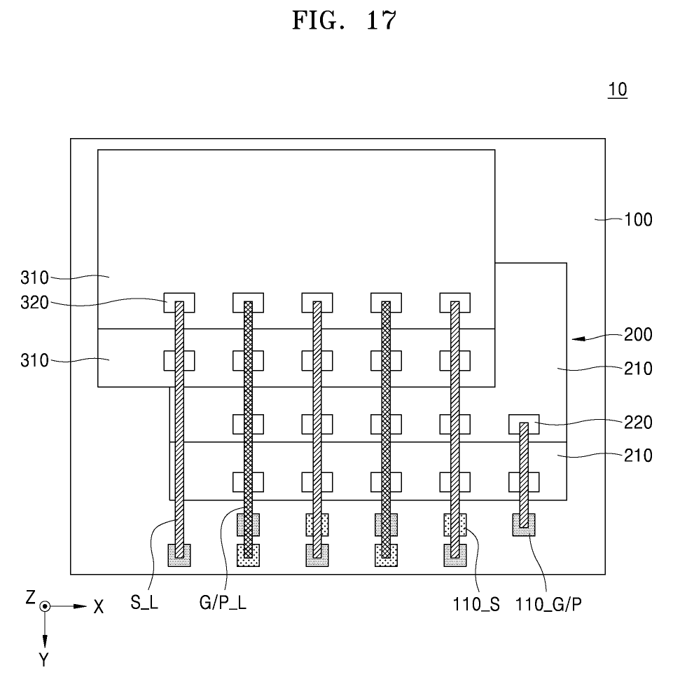

Referring to FIG. 17, the conductive patterns G/P_L and S_L electrically connecting the second semiconductor chip pads 320 with the substrate pads 110_S and 110_G/P positioned in the second row are formed.

The conductive patterns G/P_L and S_L may be formed on the insulating patterns I_L (see FIG. 16). In this case, among the conductive patterns G/P_L and S_L electrically connecting the second semiconductor chip pad 320 with the substrate pads 110_S and 110_G/P positioned in the second row, the conductive pattern G/P_L that does not overlap the first semiconductor chip 210 in the second horizontal direction Y may not be formed on the insulating pattern I_L. In the present specification, the conductive patterns G/P_L and S_L electrically connecting the second semiconductor chip pads 220 with the substrate pads 110_S and 110_G/P positioned in the second row may be referred to as second conductive patterns.

In some aspects, the present disclosure provides a method of manufacturing a semiconductor package as follows. The method of manufacturing a semiconductor package includes providing a package substrate including substrate pads positioned in a first row and a second row on a top surface of the package substrate, mounting a first chip stack structure including first semiconductor chips that are offset-stacked in a first direction on the package substrate, mounting a second chip stack structure that includes second semiconductor chips offset-stacked in the first direction and that is offset-stacked in each of the first direction and a second direction on the first chip stack structure, forming first conductive patterns electrically connecting the first semiconductor chips with the substrate pads, respectively, forming insulating patterns on the first conductive patterns overlapping the second semiconductor chips in the first direction among the first conductive patterns, respectively, and forming second conductive patterns electrically connecting the second semiconductor chips with the substrate pads, respectively, where the substrate pads positioned in the first row are arranged to be shifted from the substrate pads positioned in the second row by a first interval.

In some implementations, the substrate pads may be divided into ground/power substrate pads and signal substrate pads, and the substrate pads positioned in each of the first rows and the second row may have ground/power substrate pads and signal substrate pads, which are alternately positioned.

In some implementations, the ground/power substrate pads may surround the signal substrate pad.

In some implementations, among the second conductive patterns, second conductive patterns overlapping the first semiconductor chips in the first direction among the second conductive patterns may be positioned on the insulating patterns.

In some implementations, each of the first conductive patterns and the second conductive patterns may be divided into a ground/power conductive pattern and a signal conductive pattern.

In some implementations, the ground/power conductive pattern and the signal conductive pattern may face each other in the second direction.

In some implementations, a first semiconductor chip pad may be positioned on a top surface of each of the first semiconductor chips, and a second semiconductor chip pad may be positioned on a top surface of each of the second semiconductor chips.

In some implementations, the insulating patterns may cover all of the exposed surfaces of the first conductive patterns.

In some implementations, after the mounting of the first chip stack structure including the first semiconductor chips that are offset-stacked in the first direction on the package substrate, the method may further include forming a support spaced apart laterally from the first chip stack structure.

In some implementations, the support may be positioned between a lowermost second semiconductor chip among the second semiconductor chips and the package substrate, and the support may be completely covered by the second chip stack structure and bent when viewed from above in a vertical direction.

While the inventive concept has been particularly shown and described with reference to some implementations thereof, it will be understood that various changes in form and details may be made therein without departing from the spirit and scope of the following claims.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a package substrate;
one or more first semiconductor chips offset-stacked in a first direction on the package substrate;
a plurality of first semiconductor chip pads spaced apart from each other in a second direction on an upper surface of each of the one or more first semiconductor chips;
one or more second semiconductor chips offset-stacked in the first direction on an uppermost first semiconductor chip of the one or more first semiconductor chips;
a plurality of second semiconductor chip pads spaced apart from each other in the second direction on an upper surface of each of the one or more second semiconductor chips; and
a plurality of substrate pads arranged in a first row and a second row on the package substrate,
wherein a lowermost second semiconductor chip of the one or more second semiconductor chips is offset-stacked, in the first direction and the second direction, on the uppermost first semiconductor chip.

2. The semiconductor package of claim 1, wherein the plurality of substrate pads comprise a plurality of ground/power substrate pads and a plurality of signal substrate pads,
wherein the plurality of ground/power substrate pads and the plurality of signal substrate pads are alternately positioned in each of the first row and the second row.

3. The semiconductor package of claim 2, wherein two or more of the plurality of ground/power substrate pads surround a signal substrate pad of the plurality of signal substrate pads.

4. The semiconductor package of claim 1, wherein the first direction and the second direction form a right angle.

5. The semiconductor package of claim 1, comprising:
a plurality of conductive patterns that connect (i) respective substrate pads of the plurality of substrate pads in the first row to respective first semiconductor chip pads of the plurality of first semiconductor chip pads and (ii) respective substrate pads of the plurality of substrate pads in the second row to respective second semiconductor chip pads of the plurality of second semiconductor chip pads,
a plurality of insulating patterns between (i) respective conductive patterns of the plurality of conductive patterns connecting the respective substrate pads in the first row to the respective first semiconductor chip pads, and (ii) respective conductive patterns of the plurality of conductive patterns connecting the respective substrate pads in the second row to the respective second semiconductor chip pads.

6. The semiconductor package of claim 5, wherein the plurality of conductive patterns comprise (i) one or more ground/power conductive patterns and (ii) one or more signal conductive patterns.

7. The semiconductor package of claim 6, wherein, among the plurality of conductive patterns, respective conductive patterns that are spaced apart from each other in a vertical direction with a respective insulating pattern therebetween are of different types of conductive pattern from one another.

8. The semiconductor package of claim 6, wherein the one or more ground/power conductive patterns and the one or more signal conductive patterns face each other in the second direction.

9. The semiconductor package of claim 1, wherein the one or more first semiconductor chips correspond to four first semiconductor chips, and
wherein the one or more second semiconductor chips correspond to four second semiconductor chips.

10. The semiconductor package of claim 1, comprising:
a support between the package substrate and the lowermost second semiconductor chip.

11. The semiconductor package of claim 10, wherein the support has a bent shape, when viewed from above in a vertical direction.

12. A semiconductor package comprising:
a package substrate;
a first chip stack structure comprising a plurality of first semiconductor chips offset-stacked in a first direction on the package substrate;
a plurality of first semiconductor chip pads in parallel and spaced apart from each other in a second direction on an upper surface of each of the plurality of first semiconductor chips;
a second chip stack structure offset-stacked in the first direction and a second direction on an upper surface of an uppermost first semiconductor chip of the plurality of first semiconductor chips, the second chip stack structure comprising a plurality of second semiconductor chips that are offset-stacked in the first direction;
a plurality of second semiconductor chip pads spaced apart from each other in the second direction on an upper surface of each of the plurality of second semiconductor chips;
a plurality of substrate pads arranged in a first row and a second row on the package substrate;
a plurality of conductive patterns connecting (i) one or more respective first semiconductor chip pads of the plurality of the first semiconductor chip pads to one or more respective substrate pads of the plurality of substrate pads and (ii) one or more respective second semiconductor chip pads of the plurality of second semiconductor chip pads to one or more respective substrate pads of the plurality of substrate pads; and
an insulating pattern positioned between respective conductive patterns of the plurality of conductive patterns facing each other in a vertical direction,
wherein the plurality of substrate pads comprise a plurality of ground/power substrate pads and a plurality of signal substrate pads,
wherein the plurality of ground/power substrate pads and the plurality of signal substrate pads are alternately positioned in each of the first row and the second row,
wherein the plurality of ground/power substrate pads face each other diagonally when viewed from above in the vertical direction, and
wherein the plurality of signal substrate pads face each other diagonally when viewed from above in the vertical direction.

13. The semiconductor package of claim 12, wherein the plurality of conductive patterns comprise one or more ground/power conductive patterns and one or more signal conductive patterns.

14. The semiconductor package of claim 13, wherein respective conductive patterns of the plurality of conductive patterns that face each other in the vertical direction are of different types of conductive patterns from one another, and
wherein respective conductive patterns of the plurality of conductive patterns that face each other laterally are of different types of conductive patterns from one another.

15. The semiconductor package of claim 12, wherein one or more substrate pads of the plurality of substrate pads in the first row overlap the plurality of first semiconductor chip pads in the first direction, and
wherein one or more substrate pads of the plurality of substrate pads in the second row overlap the plurality of second semiconductor chip pads in the first direction.

16. The semiconductor package of claim 12, comprising:
a support between the package substrate and a lowermost second semiconductor chip of the plurality of second semiconductor chips.

17. The semiconductor package of claim 16, wherein the support is completely covered by the second chip stack structure when viewed from above in the vertical direction.

18. A semiconductor package comprising:
a package substrate;
a first chip stack structure comprising a plurality of first semiconductor chips offset-stacked in a first direction on the package substrate,
a plurality of first semiconductor chip pads in parallel and spaced apart from each other in a second direction on an upper surface of each of the plurality of first semiconductor chips,
a second chip stack structure offset-stacked in each of the first direction and a second direction perpendicular to the first direction, on an upper surface of an uppermost first semiconductor chip of the plurality of first semiconductor chips, the second chip stack structure comprising a plurality of second semiconductor chips offset-stacked in the first direction;
a plurality of second semiconductor chip pads spaced apart from each other in the second direction on a top surface of each of the plurality of second semiconductor chips;
a plurality of substrate pads arranged in a first row and a second row on the package substrate;
a plurality of conductive patterns connecting the first semiconductor chip pad to the substrate pads and the second semiconductor chip pad to the substrate pads; and
an insulating pattern between respective conductive patterns of the plurality of conductive patterns facing each other in a vertical direction,
wherein the plurality of substrate pads comprise a plurality of ground/power substrate pads and a plurality of signal substrate pads that are alternately positioned in each of a first row and a second row,
wherein the plurality of ground/power substrate pads face each other diagonally when viewed from above in the vertical direction,
wherein the plurality of signal substrate pads face each other diagonally when viewed from above in the vertical direction,
wherein the plurality of conductive patterns comprise a plurality of ground/power conductive patterns and a plurality of signal conductive patterns that are alternately positioned,
wherein respective substrate pads of the plurality of substrate pads in the first row overlap the plurality of first semiconductor chip pads in the first direction,
wherein respective substrate pads of the plurality of substrate pads in the second row overlap the plurality of second semiconductor chip pads in the first direction, and
wherein at least one of the respective substrate pads in the first row does not overlap at least one of the respective substrate pads in the second row in the first direction.

19. The semiconductor package of claim 18, comprising:
a support between the package substrate and a lowermost second semiconductor chip of the plurality of second semiconductor chips,
wherein the support has a bent shape when viewed from above in the vertical direction.

20. The semiconductor package of claim 18, wherein, among the conductive patterns, respective conductive patterns that are spaced apart from each other in a vertical direction with the insulating pattern therebetween are of different types of conductive pattern from one another.
